(19) United States
(12) Patent Application Publication
(10) Pub. No.: US 2024/0114730 A1
(43) Pub. Date: Apr. 4, 2024

(54) DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventors: Gaobo LIN, Shenzhen (CN); Lingling WANG, Shenzhen (CN)

(73) Assignee: Shenzhen China Star Optoelectronics Semiconductor Display Technology Co., Ltd., Shenzhen (CN)

(21) Appl. No.: 18/070,684

(22) Filed: Nov. 29, 2022

(30) Foreign Application Priority Data
Sep. 30, 2022 (CN) 202211214862.5

(51) Int. Cl. H01L 31/036

(52) U.S. Cl. CPC H01L 27/3272; H01L 51/56; H01L 2227/323

(57) ABSTRACT

A display panel and a manufacturing method thereof are provided. The display panel includes a thin film transistor. The thin film transistor includes a channel, a first conductive portion and a second conductive portion disposed on two sides of the channel, an interlayer insulation layer, a first electrode, and a second electrode. Wherein, the display panel includes a first via hole and a second via hole, the first via hole penetrates through the interlayer insulation layer and exposes a surface and a side of the first conductive portion, a first light-shielding conductive element is filled in the first via hole, the second via hole penetrates through the interlayer insulation layer and exposes a surface and a side of the second conductive portion, and the second light-shielding conductive element is filled in the second via hole.

### RELATED APPLICATION

This application claims the benefit of priority of China Patent Application No. 202211214862.5 filed on Sep. 30, 2022, the contents of which are incorporated by reference as if fully set forth herein in their entirety.

### BACKGROUND OF INVENTION

### Field of Invention

The present application relates to a display technology field, and specifically to a display panel and manufacturing method thereof.

### Description of Prior Art

Comparing to liquid crystal displays, organic light emitting diode (OLED) display panels have advantages of being thinner and lighter, good display effect, a high resolution, wide color gamut, lower power consumption, and being able to realize flexible display, etc., so that the OLED display panels are developed rapidly in recent years and have become a preferred display panel type of mobile terminals.

Driving circuit layers in the OLED display panels are provided with thin film transistors. Channel regions in active layers of the thin film transistors have a light sensitive characteristic, so they are prone to be directly irradiated by external ambient light and light emitted by OLED light-emitting units, or to be irradiated after the light being reflected, which leads to problems of deterioration of performance and reduction of reliability of thin film transistor devices. The problems need to be solved urgently.

### SUMMARY OF INVENTION

The present application provides a display panel and a manufacturing method thereof, which can effectively solve the problems of deterioration of device performance and reduction of reliability being prone to be generated in the thin film transistors of the current OLED display panels incurred by the channels being irradiated by light.

On one aspect, the present application provides a display panel. The display panel includes a base layer and a thin film transistor disposed on a side of the base layer. Wherein, the thin film transistor includes:
an active layer disposed on the side of the base layer and including a channel, and a first conductive portion and a second conductive portion disposed on two side of the channel;
an interlayer insulation layer disposed on a side that the base substrate faces toward the active layer and the active layer faces away the base layer; and a first electrode and a second electrode disposed on a side
of the interlayer insulation layer facing away the base layer.

Wherein, the display panel further includes a first via hole, a second via hole, a first light-shielding conductive element, and a second light-shielding conductive element.

The first via hole penetrates through the interlayer insulation layer and exposes a surface and a side of the first conductive portion. The first light-shielding conductive element is filled in the first via hole. The first electrode is electrically connected to the first conductive portion through the first light-shielding conductive element.

The second via hole penetrates through the interlayer insulation layer and exposes a surface and a side of the second conductive portion. The second light-shielding conductive element is filled in the second via hole. The second electrode is electrically connected to the second conductive portion through the second light-shielding conductive element.

Optionally, the display includes a base substrate and a light-shielding metal layer disposed on a side of the base substrate, and the base layer is disposed on a side that the base substrate faces toward the light-shielding metal layer and the light-shielding metal layer faces away the base substrate. Wherein, the second via hole further penetrates through the base layer and exposes the light-shielding metal layer, and the second electrode is electrically connected to the second conductive portion and the light-shielding metal layer through the second light-shielding conductive element.

Optionally, the second light-shielding conductive element includes a first portion and a second portion, an orthogonal projection of the first portion on the base substrate is configured to overlap with an orthogonal projection of the second conductive portion on the base substrate, an orthogonal projection of the second portion on the base substrate and the orthogonal projection of the second conductive portion on the base substrate are configured to be staggered, and the first portion and the second portion are disposed adjacently.

Optionally, the side of the first conductive portion and the side of the second conductive portion are both inclined surfaces.

Optionally, the thin film transistor further includes a gate insulation layer and a gate electrode, the gate insulation layer is disposed on a side of the active layer facing away the base layer, the gate electrode is disposed on a side of the gate insulation layer facing away the base layer, and the interlayer insulation layer is disposed on a side that the gate insulation layer faces toward the gate electrode and the gate electrode facing away the base layer. Wherein, an orthogonal projection of the gate electrode on the base substrate, and orthogonal projections of the first electrode and the second electrode on the base substrate are configured to be staggered.

Optionally, an orthogonal projection of the first electrode on the active layer completely covers the first conductive portion, and an orthogonal projection of the second electrode on the active layer completely covers the second conductive portion.

Optionally, the first electrode is one of a source electrode or a drain electrode, the second electrode is another one of the source electrode or the drain electrode, and materials of the first electrode, the second electrode, the first light-shielding conductive element, and the second light-shielding conductive element are same.

On another aspect, the present application provides a manufacturing method of the display panel. The manufacturing method of the display panel includes following steps:
forming an active layer being patterned on a side of a base layer;
performing a conductorization process on the active layer being patterned, so that a channel, and a first conductive portion and a second conductive portion disposed on two side of the channel are formed;
forming an interlayer insulation layer on a side that the substrate faces toward the active layer and the active layer faces away the base layer, and forming a first via hole and a second via hole penetrating through the interlayer insulation layer, wherein the first via hole exposes a surface and a side of the first conductive portion, and the second via hole exposes a surface and a side of the second conductive portion;
forming a conductive layer being patterned on a side of the interlayer insulation layer facing away the base layer, wherein the conductive layer includes a first light-shielding conductive element filled in the first via hole, a second light-shielding conductive element filled in the second via hole, and a first electrode and a second electrode disposed on a side of the interlayer insulation layer facing away the base layer. The first electrode is electrically connected to the first conductive portion through the first light-shielding conductive element. The second electrode is electrically connected to the second conductive portion through the second light-shielding conductive element.

Optionally, before forming the active layer being patterned on the side of the base layer, the manufacturing method of the display panel further includes following steps:
providing a base substrate; and forming a light shielding metal layer being patterned on a side of the base substrate;
forming the base layer on a side that the base substrate faces toward the light-shielding metal layer and the light-shielding metal layer faces away the base substrate.

Wherein, the second via hole further penetrates through the base layer and exposes the light-shielding metal layer, and the second electrode is electrically connected to the second conductive portion and the light-shielding metal layer through the second light-shielding conductive element.

Optionally, before performing the conductorization process on the active layer being patterned, the manufacturing method of the display panel further includes following steps:
forming a gate insulation layer being patterned and a gate electrode being patterned on a side of the active layer being patterned facing away the base layer. The gate electrode is located on a side of the gate insulation layer facing away the base layer.

Wherein, orthogonal projections of the first electrode and the second electrode on the base substrate, and an orthogonal projection of the gate electrode on the base substrate are configured to be staggered.

The present application provides the display panel and the manufacturing method thereof. The first light-shielding conductive element and the second light-shielding conductive element in the display panel can protect the channel of thin film transistor more effectively, which greatly reduces chances of problems of device performance deterioration and reliability reduction appearing in the thin film transistor incurred by lateral light irradiating on the channel, and improves device performance of the thin film transistor and display stability of the display panel.

### DESCRIPTION OF DRAWINGS

To more clearly illustrate technical solutions of embodiments of the present application, the accompanying figures required for illustrating embodiments will be described in brief. Obviously, the accompanying figures described below are only part of the embodiments of the present application, from which figures those skilled in the art can derive further figures without making any inventive efforts.

FIG. 1 is a sectional schematic diagram of a region of a display panel provided with a thin film transistor provided by one embodiment of the present application.

FIG. 2 is a sectional schematic diagram of forming a light-shielding metal layer being patterned on a side of a base substrate provided by one embodiment of the present application.

FIG. 3 is a sectional schematic diagram of forming a base layer on a side that the base substrate faces toward a light-shielding metal layer and the light-shielding metal layer faces away the base substrate provided by one embodiment of the present application.

FIG. 4 is a sectional schematic diagram of forming an active layer being patterned on a side of the base layer facing away the base substrate provided by one embodiment of the present application.

FIG. 5 is a sectional schematic diagram of forming a gate insulation layer being patterned and a gate electrode on a side of the active layer facing away the base layer and performing a conductorization process provided by one embodiment of the present application.

FIG. 6 is a sectional schematic diagram of a first via hole and a second via hole provided by one embodiment of the present application.

FIG. 7 is a sectional schematic diagram of forming a conductive layer being patterned on a side of the interlayer insulation layer facing away the base layer.

FIG. 8 is a sectional schematic diagram of forming a passivation layer on a side that the interlayer insulation layer faces toward the conductive layer and the conductive layer faces away the base layer.

### DETAILED DESCRIPTION OF EMBODIMENTS

The technical solutions in the embodiments of the present application are clearly and completely described in the following with reference to the accompanying drawings in the embodiments of the present application. Obviously, the described embodiments are only part of the embodiments of the present application, but are not all embodiments of the present application. All other embodiments obtained by those skilled in the art based on the embodiments of the present application without creative efforts are within the scope of the present application. Besides, it should be understood that the specific embodiments described herein are merely for describing and explaining the present disclosure and are not intended to limit the present disclosure. In the present application, unless opposite stated, the orientation words used such as “upper” and “lower” generally refer to the upper and lower directions of the device in actual using or working state, and specifically refer to the drawing directions in the drawings, and “inner” and “outer” refer to the outline of the device.

The following disclosure provides many different embodiments or examples for implementing the different structures of the present application. In order to simplify the disclosure of the present application, the components and configurations of the specific examples are described below. Of course, they are merely examples and are not intended to limit the present application. In addition, the present application may repeat reference numerals and/or reference numerals in different examples, which are for the purpose of simplicity and clarity, and do not indicate the relationship between the various embodiments and/or arrangements discussed. Moreover, the present application provides embodiments of various specific processes and materials, but one of ordinary skill in the art will recognize the use of other processes and/or the use of other materials. The details are described below respectively. It should be noted that a description order of the following embodiments is not intended to limit a preferred order of the embodiments.

FIG. 1 is a sectional schematic diagram of a region of a display panel provided with a thin film transistor provided by one embodiment of the present application. As illustrated in FIG. 1, the present application provides a display panel. The display panel includes: a base layer 30 and a thin film transistor disposed on a side of the base layer 30. Wherein, the thin film transistor includes: an active layer 40 disposed on the side of the base layer 30 and including a channel 40, and a first conductive portion 41 and a second conductive portion 42 disposed on two side of the channel 43; an interlayer insulation layer 70 disposed on a side that the base substrate 30 faces toward the active layer 40 and the active layer 40 faces away the base layer 30; and a first electrode 81 and a second electrode 82 disposed on a side of the interlayer insulation layer 70 facing away the base layer 30. Wherein, the display panel further includes a first via hole 71, a second via hole 72, a first light-shielding conductive element 83, and a second light-shielding conductive element 84. The first via hole 71 penetrates through the interlayer insulation layer 70 and exposes a surface 411 and a side 412 of the first conductive portion 41. The first light-shielding conductive element 83 is filled in the first via hole 71. The first electrode 81 is electrically connected to the first conductive portion 41 through the first light-shielding conductive element 83. The second via hole 72 penetrates through the interlayer insulation layer 70 and exposes a surface 421 and a side 422 of the second conductive portion 42. The second light-shielding conductive element 84 is filled in the second via hole 72. The second electrode 82 is electrically connected to the second conductive portion 42 through the second light-shielding conductive element 84.

In the display panel provided by the present application, because the first via hole 71 penetrates through the interlayer insulation layer 70 and exposes the surface 411 and the side 412 of the first conductive portion 41, the first light-shielding conductive element 83 filled in the first via hole 71 can form a stable electrical connection between the first electrode 81 and the first conductive portion 41. Moreover, a lateral light blocking range of the first light-shielding conductive element 83 can extend from the first electrode 81 to the base layer 30, which greatly enhances light blocking ability of the side of the first conductive portion 41 facing away the channel 43. Because the second via hole 72 penetrates through the interlayer insulation layer 70 and exposes the surface 421 and the side 422 of the second conductive portion 42, the second light-shielding conductive element 84 filled in the second via hole 72 can form a stable electrical connection between the second electrode 82 and the second conductive portion 42. Moreover, a lateral light blocking range of the second light-shielding conductive element 84 can extend from the second electrode 82 to the base layer 30, which greatly enhances light blocking ability of the side of the second conductive portion 42 facing away the channel 43. Correspondingly, as the first light-shielding conductive element 83 and the second light-shielding conductive element 84 can realize electrical connection function and can have a greater lateral light blocking range and a stronger lateral light blocking ability simultaneously, so the channel 43 of the thin film transistor can be much more effectively protected. Chances of problems of device performance deterioration and reliability reduction appearing in the thin film transistor incurred by lateral light irradiating on the channel 43 is greatly reduced, and device performance of the thin film transistor and display stability of the display panel are improved.

In addition, as the first via hole 71 and the second via hole 72 respectively expose the sides of the first conductive portion 41 and the second conductive portion 42, so the first light-shielding conductive element 83 filled in the first via hole 71 can be lap joint with the surface 411 and the side 412 of the first conductive portion 41 at the same time, the second light-shielding conductive element 84 filled in the second via hole 72 can be lap joint with the surface 421 and the side 422 of the second conductive portion 42 at the same time, and each light-shielding conductive element and corresponding conductive portions have larger lap-joint areas and stronger lap-joint stability therebetween. Therefore, contact resistance can be effectively reduced, resistance-capacitance (RC) delay of the display panel can be decreased, and the display effect of the display panel can be improved.

Furthermore, the display panel is an organic light emitting diode (OLED) display panel, including a flexible OLED display panel or a rigid OLED display panel. However, a type of the display panel is not limited by the present application. The display panel can also be a liquid crystal display panel or an inorganic light emitting diode (LED) display panel. The base layer 30 is a buffer function layer. The first electrode 81 is one of a source electrode or a drain electrode, the second electrode 82 is another one of the source electrode or the drain electrode, and materials of the first electrode 81, the second electrode 82, the first light-shielding conductive element 83, and the second light-shielding conductive element 84 are same, i.e., the first electrode 81, the second electrode 82, the first light-shielding conductive element 83, and the second light-shielding conductive element 84 can be formed by one film forming process.

Furthermore, the thin film transistor is a top-gate thin film transistor, and the thin film transistor further includes a gate insulation layer 50 and a gate electrode 60. Wherein, the gate insulation layer 50 is disposed on a side of the active layer 40 facing away the base layer 30, the gate electrode 60 is disposed on a side of the gate insulation layer 50 facing away the base layer 30, and the interlayer insulation layer 70 is disposed on a side that the base layer 30 faces toward the active layer 40, the active layer 40 faces toward the gate insulation layer 50, the gate insulation layer 50 faces toward the gate electrode 60, and the gate electrode 60 faces away the base layer 30.

In some embodiments of the present application, the display includes a base substrate 10 and a light-shielding metal layer 20 disposed on a side of the base substrate 10, and the base layer 30 is disposed on a side that the base substrate 10 faces toward the light-shielding metal layer 20 and the light-shielding metal layer 20 faces away the base substrate 10. Wherein, the second via hole 72 further penetrates through the base layer 30 and exposes the light-shielding metal layer 20, and the second electrode 82 is electrically connected to the second conductive portion 42 and the light-shielding metal layer 20 through the second light-shielding conductive element 84.

In the prior art, two via holes spaced apart are needed for realizing the second electrode 82 to be electrically connected to an electrode region in the active layer 40 and the light-shielding metal layer 20. The opening process is more complicated, and a gap region between the two spaced vias is filled with an interlayer insulation layer 70 made of a transparent material. The existence of the gap region creates conditions for the external light to irradiate the channel 43 of the active layer 40, which generates unfavorable effects on the device performance and reliability of the thin film transistor. However, in the display panel provided by the present application, because the second via hole 72 further penetrates through the base layer 30 and exposes the light-shielding metal layer 20, the second light-shielding conductive element 84 filled in the second via hole 72 can realize electrical connection with the light-shielding metal layer 20 and the second conductive portion 42 while maintains an integrated structure. Therefore, the electrical connection function and realization of the light-shielding function is ensured, while the gap region in the prior art is eliminated, which further reduces chances of the problems of device performance deterioration and reliability appearing in the thin film transistor, and further improves the device performance of the thin film transistor and display stability of the display panel.

The structure of the second light-shielding conductive element 84 is further described as follows. Specifically, the second via hole 72 is a one-piece complete hole structure. The second light-shielding conductive element 84 filled in the second via hole 72 includes a first portion 841 and a second portion 842. An orthogonal projection of the first portion 841 on the base substrate 10 is configured to overlap with an orthogonal projection of the second conductive portion 42 on the base substrate 10, an orthogonal projection of the second portion 842 on the base substrate 10 and the orthogonal projection of the second conductive portion 42 on the base substrate 10 are configured to be staggered, and the first portion 841 and the second portion 842 are disposed adjacently. That is, the first portion 841 and the second portion 842 are integrated into a complete one-piece structure, thereby effectively eliminating the gap region in the prior art and reducing the chances of the problems of device performance deterioration and the reliability problem appearing in the thin film transistor. Furthermore, the first portion 841 is in lap joint with the surface 421 and the side 422 of the second conductive portion 42, and the second portion 842 is in lap joint with the surface of the light-shielding metal layer 20 exposed by the second via hole 72.

Furthermore, because the second via hole 72 penetrates through the interlayer insulation layer 70 and exposes the surface 411 and the side 412 of the first conductive portion 41 while further penetrates through the base layer 30 and exposes the light-shielding metal layer 20, the lateral light blocking range of the second light-shielding conductive element 84 filled in the second via hole 72 can extend from the second electrode 82 to the light-shielding metal layer 20, which further improves light blocking ability of the side of the second conductive portion 42 facing away the channel 43, thereby being able to perform more effective protection on the channel 43 of the thin film transistor.

In some embodiments of the present application, the first via hole 71 not only exposes the surface 411 and the side 412 of the first conductive portion 41, but also exposes a surface of the base layer 30. Correspondingly, the first light-shielding conductive element 83 filled in the first via hole 71 not only includes a portion overlapping with the first conductive portion 41, but also includes a portion located on a side of the first conductive portion 41 facing away the channel 43. The structure of the first light-shielding conductive element 83 can also increase an area of the light-shielding region in the horizontal direction to a certain extent and can enhance light-shielding effect. Furthermore, at least a part of an orthogonal projection of the first light-shielding conductive element 83 on the base substrate 10 does not overlap with an orthogonal projection of the light-shielding metal layer 20 on the base substrate 10.

In some embodiments of the present application, the side 412 of the first conductive portion 41 and the side 422 of the second conductive portion 42 are both inclined surfaces. As the side 412 of the first conductive portion 41 and the side 422 of the second conductive portion 42 are both inclined surfaces, so a larger lap-joint area can be between the first light-shielding conductive element 83 and the side 412 of the first conductive portion 41, and a larger lap-joint area can be between the second light-shielding conductive element 84 and the side 422 of the second conductive portion 42. Therefore, contact resistance can be effectively reduced, resistance-capacitance delay of the display panel can be decreased, and the display effect of the display panel can be improved.

In some embodiments of the present application, an orthogonal projection of the gate electrode 60 on the base substrate 10, and orthogonal projections of the first electrode 81 and the second electrode 82 on the base substrate 10 are configured to be staggered. In the prior art, the overlap between the gate electrode 60, and the source electrode and the drain electrode can generate overlapping capacitance, which increases the resistance-capacitance delay in the display panel. However, in the present application, by configuring the orthogonal projection of the gate electrode 60 on the base substrate 10, and the orthogonal projections of the first electrode 81 and the second electrode 82 on the base substrate 10 to be configured to be staggered, the overlapping capacitance between the gate electrode 60, and the first electrode 81 and the second electrode 82 can be effectively reduced, resistance-capacitance delay of the display panel can be decreased, and the display effect of the display panel can be improved.

In some embodiments of the present application, an orthogonal projection of the first electrode 81 on the active layer 40 completely covers the first conductive portion 41, and an orthogonal projection of the second electrode 82 on the active layer 40 completely covers the second conductive portion 42. Because the orthogonal projections of the first electrode 81 and the second electrode 82 on the active layer 40 completely cover the first conductive portion 41 and the second conductive portion 42, the ability of the first electrode 81 and the second electrode 82 for blocking light from the side of the first electrode 81 and the second electrode 82 facing away the substrate layer 30 can be effectively improved. The chances of the problems of device performance deterioration and reliability reduction appearing in the thin film transistor incurred by lateral light irradiating on the channel 43 are greatly reduced, and device performance of the thin film transistor and display stability of the display panel are improved.

In some embodiments of the present application, the display panel further includes a passivation layer 90. The passivation layer 90 is disposed on a side that the interlayer insulation layer 70 faces away the base layer 30, and the first electrode 81 and the second electrode 82 face away the base layer 30.

In some embodiments of the present application, the display panel further includes a light-emitting function layer disposed on a side of the passivation layer 90 facing away the substrate layer 30. The light-emitting function layer includes light-emitting units disposed in an array manner. The thin film transistor is configured to control the light-emitting units to emit light. The light-emitting units are configured to realize display functions.

In some embodiments of the present application, the display panel further includes an encapsulation layer disposed on a side of the light-emitting function layer facing away the substrate layer 30. The encapsulation layer can prevent external water and oxygen from intruding into an interior of the display panel, which improves display stability of the display panel, and prolongs service life of the display panel.

In some embodiments of the present application, the display panel can further include a touch function layer and an optical function layer. For example, the touch function layer can be disposed on a side of the encapsulation layer facing away the base layer, and is configured to allow the display panel has a touch function at the same time. The optical function layer can be an anti-reflective layer disposed on a side of the encapsulation layer or the touch function layer facing away the base layer 30, e.g., a polarizer sheet or a color filter, etc.

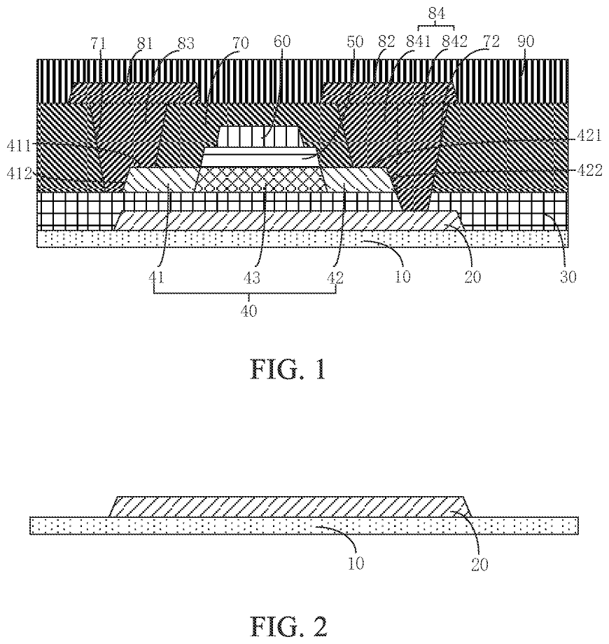

On another aspect, the present application further provides a manufacturing method of the display panel. Specifically, please refer to FIG. 2 to FIG. 8, the manufacturing method of the display panel includes following steps:

Step S01: providing a base substrate 10; and forming a light shielding metal layer 20 being patterned on a side of the base substrate 10.

Step S02: forming the base layer 30 on a side that the base substrate 10 faces toward the light-shielding metal layer 20 and the light-shielding metal layer 20 faces away the base substrate 10.

Step 03: forming the active layer 40 on a side of the base layer 30 facing away the base substrate 10.

Step S04: performing a conductorization process on the active layer 40 being patterned, so that a channel 43, and a first conductive portion 41 and a second conductive portion 41 disposed on two side of the channel 43 are formed.

Step S05: forming an interlayer insulation layer 70 disposed on a side that the base substrate 30 faces toward the active layer 40 and the active layer 40 faces away the base layer 30, and forming a first via hole 71 and a second via hole 72 penetrating through the interlayer insulation layer 70 by a photo process.

Step S06: forming a conductive layer 80 being patterned on a side of the interlayer insulation layer 70 facing away the base layer 30.

Step: 07: forming a passivation layer 90 on a side that the interlayer insulation layer 70 faces toward the conductive layer 80 and the conductive layer 80 faces away the base layer 30.

FIG. 2 is a sectional schematic diagram of forming a light-shielding metal layer being patterned on a side of the base substrate provided by one embodiment of the present application. With reference to FIG. 2, in the step S01, for example, the base substrate 10 is a glass substrate. Before forming the light-shielding metal layer 20 being patterned on the side of the base substrate 10, a cleaning step for the base substrate 10 is further included. The light-shielding metal layer 20 can be a single-layer metal layer or a composite metal layer formed by at least one of Mo, Al, Cu, and Ti, and the type of the composite metal layer can be Mo/Cu, MoTi/Cu, Mo/Al, MoTi/Cu/MoTi, etc. Furthermore, a thickness of the light-shielding metal layer 20 ranges from 500-10000 angstroms.

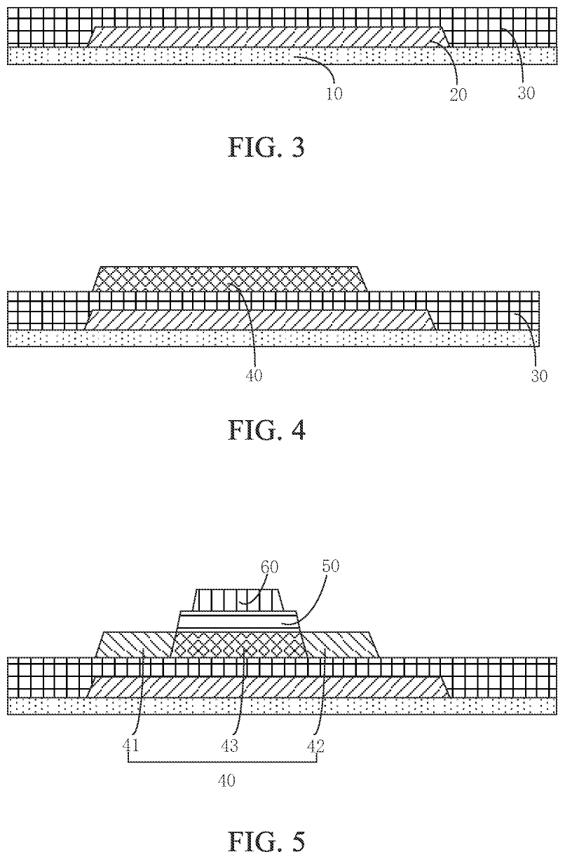

FIG. 3 is a sectional schematic diagram of forming the base layer on a side that the base substrate faces toward a light-shielding metal layer and the light-shielding metal layer faces away the base substrate provided by one embodiment of the present application. With reference to FIG. 3, in the step S02, the base layer 30 is a buffer function layer. A material of the base layer 30 can be a single-layer inorganic film or a double-layer inorganic film formed by at least one of Si₃N₄, SiO₂, and SiON. Furthermore, the thickness of the base layer 30 ranges from 1000-10000 angstroms.

FIG. 4 is a sectional schematic diagram of forming the active layer being patterned on the side of the base layer facing away the base substrate provided by one embodiment of the present application. With reference to FIG. 4, in the step S03, for example, a material of the active layer 40 is a metal oxide, e.g., indium gallium zinc oxide (IGZO), indium tin zinc oxide (ITZO), or indium gallium zinc tin oxide (IGZTO). Furthermore, a thickness of the active layer 40 ranges from 100-1000 angstroms.

FIG. 5 is a sectional schematic diagram of forming the gate insulation layer being patterned and the gate electrode on a side of the active layer facing away the base layer and performing a conductorization process provided by one embodiment of the present application. With reference to FIG. 5, in the step S04, before performing the conductorization process on the active layer 40, forming a gate insulation layer 50 disposed on a side that the base substrate 30 faces toward the active layer 40 being patterned and the active layer 40 being patterned faces away the base layer 30 at first. Then, forming a gate metal layer with an entire surface on a side of an entire surface of the gate insulation layer 50 facing away the substrate layer 30. After that, using a photomask to define a gate region of the thin film transistor, and performing a wet etching process on the entire surface of the gate electrode metal layer to form the gate electrode 60 being patterned. Then, using the gate electrode 60 as a mask, and using a self-aligned gate process to perform a dry etching process on the entire surface of the gate insulation layer 50 to form the gate insulation layer 50 being patterned. Furthermore, a material of the gate insulation layer 50 is SiO₂, and a thickness of the gate insulation layer 50 ranges from 1000-3000 angstroms. The gate metal layer and the gate electrode 60 can be a single-layer metal layer or a composite metal layer formed of at least one of Mo, Al, Cu, or Ti. Composite metal layer types can be Mo/Al/Mo, Al/Mo, Mo/Cu, MoTi/Cu, MoTi/Cu/MoTi, etc. A thickness of the gate electrode metal layer and the gate electrode 60 ranges from 500-1000 angstroms.

Furthermore, in the step S04, after forming the gate insulation layer 50 being patterned and the gate electrode 60 being patterned, using the gate electrode 60 being patterned and the gate insulation layer 50 being patterned as masks, and adopting a plasma process to perform the conductorization process on the active layer 40 being patterned to form the channel 43, and the first conductive portion 41 and the second conductive portion 42 on two sides of the channel 43 in the active layer 40. Specifically, the first conductive portion 41 and the second conductive portion 42 are formed by performing a conductorization process on a metal oxide semiconductor manufactured together with the channel 43, so as to have conductive properties. Furthermore, under a shielding effect of the gate electrode 60 and the gate insulation layer 50, a material of the channel 43 of the active layer 40 is still a metal oxide semiconductor, which has semiconductor properties.

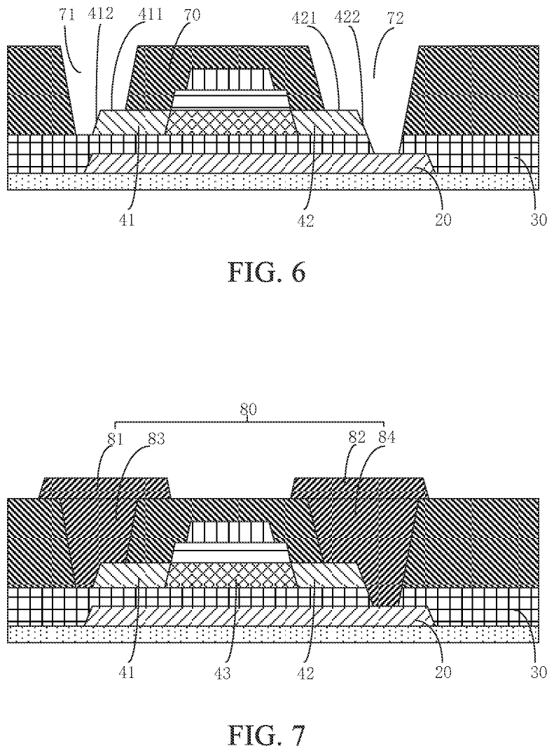

FIG. 6 is a sectional schematic diagram of the first via hole and the second via hole provided by one embodiment of the present application. With reference to FIG. 6, in the step S05, a material of the interlayer insulation layer 70 is SiO₂, and a thickness of the interlayer insulation layer 70 ranges from 3000-10000 angstroms. A photo process and an etching process are included. The first via hole 71 and the second via hole 72 are formed through the etching process. Wherein, the first via hole 71 exposes a surface 411 and a side 412 of the first conductive portion 41, and the second via hole 72 exposes a surface 421 and a side 422 of the second conductive portion 42.

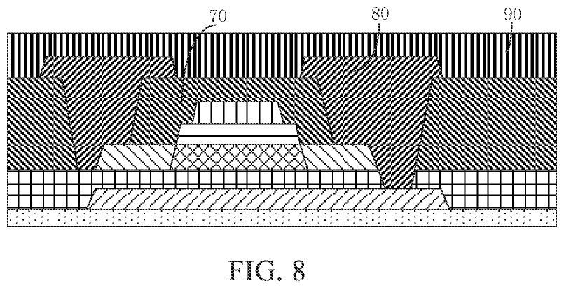

FIG. 7 is a sectional schematic diagram of forming a conductive layer being patterned on a side of the interlayer insulation layer facing away the base layer. With reference to FIG. 7, in the step S06, the conductive layer 80 be a single-layer metal layer or a composite metal layer formed of at least one of Mo, Al, Cu, or Ti, composite metal layer types can be Mo/Al/Mo, Al/Mo, Mo/Cu, MoTi/Cu, MoTi/Cu/MoTi, etc., the conductive layer 80 includes a first light-shielding conductive element 83 filled in the first via hole 71, a second light-shielding conductive element 84 filled in the second via hole 72, and a first electrode 81 and a second electrode 82 disposed on a side of the interlayer insulation layer 70 facing away the base layer 30, the first electrode 81 is electrically connected to the first conductive portion 41 through the first light-shielding conductive element 83, and the second electrode 82 is electrically connected to the second conductive portion 42 through the second light-shielding conductive element 84. Furthermore, thicknesses of the first electrode 81 and the second electrode 82 are same, e.g., ranging from 500-10000 angstroms.

Furthermore, the second via hole 72 further penetrates through the base layer 30 and exposes the light-shielding metal layer 20, and the second electrode 82 is electrically connected to the second conductive portion 42 and the light-shielding metal layer 20 through the second light-shielding conductive element 84.

Furthermore, orthogonal projections of the first electrode 81 and the second electrode 82 on the base substrate 10, and an orthogonal projection of the gate electrode 60 on the base substrate 10 are configured to be staggered.

Furthermore, an orthogonal projection of the first electrode 81 on the active layer 40 completely covers the first conductive portion 41, and an orthogonal projection of the second electrode 82 on the active layer 40 completely covers the second conductive portion 42.

FIG. 8 is a sectional schematic diagram of forming a passivation layer on a side that the interlayer insulation layer faces toward the conductive layer and the conductive layer faces away the base layer. With reference to FIG. 8, in the step S07, a material of the passivation layer 90 is SiO₂, and a thickness of the passivation layer 90 ranges from 1000-5000 angstroms.

In summary, the present application provides a display panel and a manufacturing method thereof. The display panel includes a thin film transistor. The thin film transistor includes a channel, a first conductive portion and a second conductive portion disposed on two sides of the channel, an interlayer insulation layer, a first electrode, and a second electrode. Wherein, the display panel includes a first via hole and a second via hole, the first via hole penetrates through the interlayer insulation layer and exposes a surface and a side of the first conductive portion, a first light-shielding conductive element is filled in the first via hole, the second via hole penetrates through the interlayer insulation layer and exposes a surface and a side of the second conductive portion, and the second light-shielding conductive element is filled in the second via hole. The first light-shielding conductive element and a second light-shielding conductive element in the display panel provided by the present application can protect the channel of thin film transistor more effectively, which greatly reduces chances of problems of device performance deterioration and reliability reduction appearing in the thin film transistor incurred by lateral light irradiating on the channel, and improves device performance of the thin film transistor and display stability of the display panel.

The above describes the display panel and manufacturing method thereof provided by the embodiments of the present application in detail. This article uses specific cases for describing the principles and the embodiments of the present application, and the description of the embodiments mentioned above is only for helping to understand the method and the core idea of the present application. Meanwhile, for those skilled in the art, will have various changes in specific embodiments and application scopes according to the idea of the present application. In summary, the content of the specification should not be understood as limit to the present application.

What is claimed is:

1. A display panel, comprising: a base layer and a thin film transistor disposed on a side of the base layer; wherein the thin film transistor comprises:
an active layer disposed on the side of the base layer and comprising a channel, and a first conductive portion and a second conductive portion disposed on two side of the channel;
an interlayer insulation layer disposed on a side that the base substrate faces toward the active layer and the active layer faces away the base layer; and
a first electrode and a second electrode disposed on a side of the interlayer insulation layer facing away the base layer;
wherein the display panel comprises a first via hole, a second via hole, a first light-shielding conductive element, and a second light-shielding conductive element;
the first via hole penetrates through the interlayer insulation layer and exposes a surface and a side of the first conductive portion, the first light-shielding conductive element is filled in the first via hole, and the first electrode is electrically connected to the first conductive portion through the first light-shielding conductive element; and
wherein the second via hole penetrates through the interlayer insulation layer and exposes a surface and a side of the second conductive portion, the second light-shielding conductive element is filled in the second via hole, and the second electrode is electrically connected to the second conductive portion through the second light-shielding conductive element.

2. The display panel as claimed in claim 1, wherein the display comprises a base substrate and a light-shielding metal layer disposed on a side of the base substrate, and the base layer is disposed on a side that the base substrate faces toward the light-shielding metal layer and the light-shielding metal layer faces away the base substrate; and
wherein the second via hole penetrates through the base layer and exposes the light-shielding metal layer, and
the second electrode is electrically connected to the second conductive portion and the light-shielding metal layer through the second light-shielding conductive element.

3. The display panel as claimed in claim 2, wherein the second light-shielding conductive element comprises a first portion and a second portion, an orthogonal projection of the first portion on the base substrate is configured to overlap with an orthogonal projection of the second conductive portion on the base substrate, an orthogonal projection of the second portion on the base substrate and the orthogonal projection of the second conductive portion on the base substrate are configured to be staggered, and the first portion and the second portion are disposed adjacently.

4. The display panel as claimed in claim 3, wherein the side of the first conductive portion and the side of the second conductive portion are inclined surfaces.

5. The display panel as claimed in claim 2, wherein the thin film transistor comprises a gate insulation layer and a gate electrode, the gate insulation layer is disposed on a side of the active layer facing away the base layer, the gate electrode is disposed on a side of the gate insulation layer facing away the base layer, and the interlayer insulation layer is disposed on a side that the gate insulation layer faces toward the gate electrode and the gate electrode facing away the base layer; and wherein an orthogonal projection of the gate electrode on the base substrate, and orthogonal projections of the first electrode and the second electrode on the base substrate are configured to be staggered.

6. The display panel as claimed in claim 5, wherein an orthogonal projection of the first electrode on the active layer completely covers the first conductive portion, and
an orthogonal projection of the second electrode on the active layer completely covers the second conductive portion.

7. The display panel as claimed in claim 1, wherein the first electrode is one of a source electrode or a drain electrode, the second electrode is another one of the source electrode or the drain electrode, and materials of the first electrode, the second electrode, the first light-shielding conductive element, and the second light-shielding conductive element are same.

8. A manufacturing method of a display panel, comprising following steps:
forming an active layer being patterned on a side of a base layer;
performing a conductorization process on the active layer being patterned, so that a channel, and a first conductive portion and a second conductive portion disposed on two side of the channel are formed;
forming an interlayer insulation layer on a side that the substrate faces toward the active layer and the active layer faces away the base layer, and forming a first via hole and a second via hole penetrating through the interlayer insulation layer, wherein the first via hole exposes a surface and a side of the first conductive portion, and the second via hole exposes a surface and a side of the second conductive portion;
forming a conductive layer being patterned on a side of the interlayer insulation layer facing away the base layer, wherein the conductive layer comprises a first light-shielding conductive element filled in the first via hole, a second light-shielding conductive element filled in the second via hole, and a first electrode and a second electrode disposed on a side of the interlayer insulation layer facing away the base layer; the first electrode is electrically connected to the first conductive portion through the first light-shielding conductive element, and the second electrode is electrically connected to the second conductive portion through the second light-shielding conductive element.

9. The manufacturing method of the display panel as claimed in claim 8, wherein before forming the active layer being patterned on the side of the base layer, the manufacturing method of the display panel comprises following steps:
providing a base substrate; and forming a light shielding metal layer being patterned on a side of the base substrate;
forming the base layer on a side that the base substrate faces toward the light-shielding metal layer and the light-shielding metal layer faces away the base substrate; and
wherein the second via hole penetrates through the base layer and exposes the light-shielding metal layer, and the second electrode is electrically connected to the second conductive portion and the light-shielding metal layer through the second light-shielding conductive element.

10. The manufacturing method of the display panel as claimed in claim 9, wherein before performing the conductorization process on the active layer being patterned, the manufacturing method of the display panel comprises following steps:
forming a gate insulation layer being patterned and a gate electrode being patterned on a side of the active layer being patterned facing away the base layer, wherein the gate electrode is located on a side of the gate insulation layer facing away the base layer, and
wherein orthogonal projections of the first electrode and the second electrode on the base substrate, and an orthogonal projection of the gate electrode on the base substrate are configured to be staggered.
